(19) United States
(12) Patent Application Publication
(10) Pub. No.: US 2011/0272028 A1
(43) Pub. Date: Nov. 10, 2011

(54) ORGANIC SOLAR CELL AND METHOD OF MANUFACTURING THE SAME

(75) Inventors: Sung-Young YUN, Suwon-si (KR); Soo-Ghang IHN, Hwaseong-si (KR); Bulliard XAVIER, Suwon-si (KR); Woong CHOI, Seongnam-si (KR)

(73) Assignee: SAMSUNG ELECTRONICS CO., LTD., Suwon-si (KR)

(21) Appl. No.: 12/903,396

(22) Filed: Oct. 13, 2010

(30) Foreign Application Priority Data
May 7, 2010 (KR) 10-2010-0042994

(51) Int. Cl. H01L 51/44; H01L 51/48

(52) U.S. Cl. 136/263; 438/82; 977/811; 257/E51.016

(57) ABSTRACT

An organic solar cell includes a first electrode, a second electrode facing the first electrode, and a photoactive layer disposed between the first and second electrodes. The photoactive layer includes inorganic nanostructures continually connected to one another, and a light-absorbing body filled among the inorganic nanostructures and including a soluble low molecular compound.

### CROSS REFERENCE TO RELATED APPLICATIONS

This application claims priority to Korean Patent Application No. 10-2010-0042994 filed on May 7, 2010, and all the benefits accruing therefrom under 35 U.S.C. §119, the entire content of which is incorporated herein by reference.

### BACKGROUND

1. Field

Provided is an organic solar cell and a method of manufacturing the same.

2. Description of the Related Art

A solar cell is a photoelectric conversion device that converts solar energy into electrical energy and thus has garnered attention as an indefinite pollution-free next generation energy resource.

A solar cell includes p-type and n-type semiconductors. When it absorbs solar energy through a photoactive layer, electron-hole pairs (“EHP”) are produced inside the semiconductors. The electrons and holes respectively move toward the n-type and p-type semiconductors and are then collected in an electrode. The energy may be used outside as electrical energy.

In general, a solar cell may be classified into inorganic and organic solar cells depending on a material forming a thin film. An organic solar cell may be classified into two different kinds depending on a photoactive layer structure such as a bi-layer p-n junction structure in which p-type and n-type semiconductors are disposed as separate layers, and a bulk heterojunction structure in which p-type and n-type semiconductors are blended with other. The bulk heterojunction structure is more efficient for separation and movement of electron-hole pairs than the bi-layer p-n junction structure.

### SUMMARY

Provided is an organic solar cell having improved efficiency in terms of a bulk heterojunction structure.

Provided is a method of manufacturing the organic solar cell.

Provided is an organic solar cell including a first electrode, a second electrode facing the first electrode, and a photoactive layer disposed between the first and second electrodes. The photoactive layer includes inorganic nanostructures continually connected to one another, and a light-absorbing body filled among the inorganic nanostructures and including a soluble low molecular compound.

The light-absorbing body may be continually connected inside the photoactive layer.

The inorganic nanostructures may be an electron acceptor, while the light-absorbing body may be an electron donor.

The inorganic nanostructures may be an n-type semiconductor, while the light-absorbing body may be a p-type semiconductor.

The inorganic nanostructures may include one selected from a metal oxide, a semiconducting compound, and a combination thereof.

In particular, the inorganic nanostructures may include one selected from zinc oxide, titanium oxide, tantalum oxide, tin oxide, zirconium oxide, lanthanum oxide, niobium oxide, copper oxide, strontium oxide, indium oxide, sodium titanate, cadmium sulfide, gallium arsenide, cadmium selenide, lead sulfide, gallium phosphide, cadmium telluride, and a combination thereof.

The soluble low molecular compound may have a mass from about 3000 Daltons or less.

In particular, the soluble low molecular compound may have a band gap energy ranging from about 1 electron volt (eV) to 2.5 electron volts (eV), and lowest unoccupied molecular orbit (“LUMO”) energy ranging from about −3.0 eV to −4.0 eV.

In addition, the soluble low molecular compound may have a size which is smaller than a gap between the inorganic nanostructures.

Furthermore, the inorganic nanostructures may include a plurality of pores, and the soluble low molecular compound may have a smaller size than the pores.

The inorganic nanostructures may include a plurality of pores having a size ranging from about 1 nanometer (nm) to about 100 nanometers (nm). The plurality of pores may be filled with the light-absorbing body.

In particular, the inorganic nanostructures may include a plurality of pores having a size ranging from about 1 nm to about 20 nm. The plurality of the pores may be filled with the light-absorbing body.

The inorganic nanostructure may have at least one shape selected from nanotubes, nano-rods, a gyroid, a network and a combination thereof.

Provided is a method of forming an organic solar cell. The method includes forming a first electrode, disposing a photoactive layer including inorganic nanostructures continually connected to one another, and a light-absorbing body including a soluble low molecular compound on the first electrode, and forming a second electrode on the photoactive layer.

The disposing a photoactive layer may include preparing the inorganic nanostructures, and filling the soluble low molecular compound as a solution among the inorganic nanostructures.

The inorganic nanostructures may be an n-type electron acceptor, while the light-absorbing body may be a p-type electron donor.

The inorganic nanostructure may include one selected from a metal oxide, a semiconducting compound, and a combination thereof.

In particular, the inorganic nanostructure may include one selected from zinc oxide, titanium oxide, tantalum oxide, tin oxide, zirconium oxide, lanthanum oxide, niobium oxide, copper oxide, strontium oxide, indium oxide, sodium titanate, cadmium sulfide, gallium arsenide, cadmium selenide, lead sulfide, gallium phosphide, cadmium telluride, and a combination thereof.

The soluble low molecular compound may include an organic material having a mass from about 3000 Daltons or less.

The soluble low molecular compound may have a band gap energy ranging from about 1 eV to about 2.5 eV, and LUMO energy ranging from about −3.0 eV to about −4.0 eV.

### BRIEF DESCRIPTION OF THE DRAWINGS

The above and other features of this disclosure will become more apparent by describing in further detail embodiments thereof with reference to the accompanying drawings, in which:

FIG. 1 is a cross-sectional view of an embodiment of an organic solar cell, according to the invention,

FIG. 2 is a cross-sectional view of another embodiment of an organic solar cell, according to the invention, and

FIGS. 3A to 3D are cross-sectional views sequentially showing an embodiment of a method of manufacturing the organic solar cell of FIG. 1.

### DETAILED DESCRIPTION

Embodiments will hereinafter be described in detail referring to the following accompanied drawings and can be easily performed by those who have common knowledge in the related art. However, these embodiments are exemplary, and this disclosure is not limited thereto. In the drawings, the thickness of layers, films, panels, regions, and the like are exaggerated for clarity. Like reference numerals designate like elements throughout the specification. As used herein, the term “and/or” includes any and all combinations of one or more of the associated listed items.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “lower,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the invention will be described in detail with reference to the accompanying drawings.

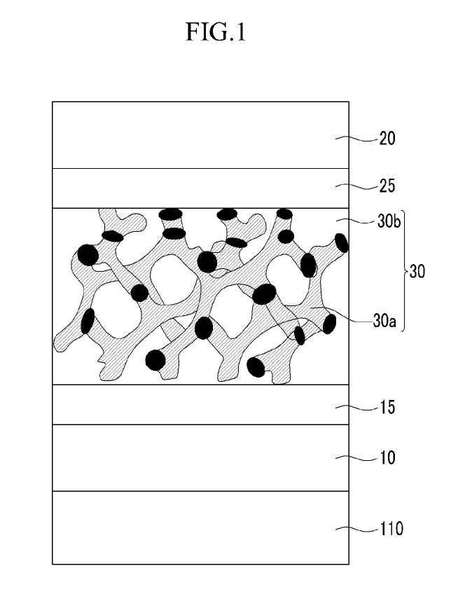

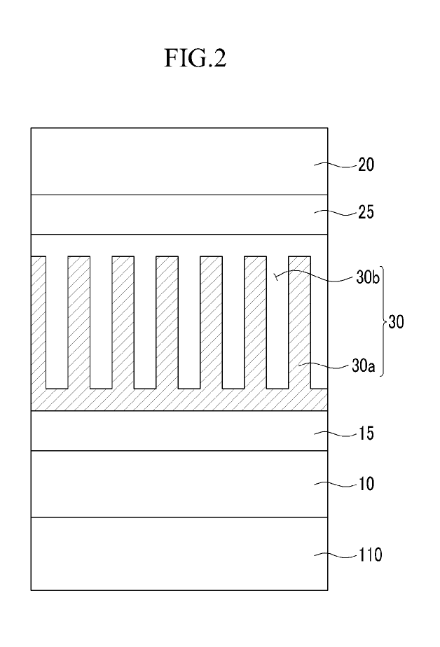

Hereinafter, referring to FIGS. 1 and 2, an organic solar cell according to embodiments of the invention is illustrated.

FIG. 1 provides a cross-sectional view showing an embodiment of an organic solar cell according to the invention, and FIG. 2 provides a cross-sectional view showing another embodiment of an organic solar cell according to the invention.

Referring to FIGS. 1 and 2, an organic solar cell includes a substrate 110, a lower electrode 10 and an upper electrode 20 disposed on the substrate 110 and facing each other, a lower auxiliary layer 15 disposed on one surface of the lower electrode 10, an upper auxiliary layer 25 disposed on one surface of the upper electrode 20, and a photoactive layer 30 disposed between the lower electrode 10 and the upper electrode 20.

The substrate 110 may include a transparent material, for example, an inorganic material such as glass or an organic material such as polycarbonate, polymethylmethacrylate, polyethylene terephthalate, polyethylene naphthalate, polyamide, and polyethersulfone.

Either of the lower electrode 10 and the upper electrode 20 may be an anode, while the other of the lower electrode 10 and the upper electrode 20 is a cathode. Either of the lower electrode 10 and the upper electrode 20 may include a transparent conductor such as indium tin oxide (“ITO”), indium zinc oxide (“IZO”), tin oxide (SnO₂), aluminum-doped ZnO, and gallium-doped ZnO, and an opaque conductor such as aluminum (Al), silver (Ag), and the like.

The lower auxiliary layer 15 and the upper auxiliary layer 25 are configured to efficiently transfer or block electric charges. In one embodiment, for example, when the lower electrode 10 is a cathode, the lower auxiliary layer 15 may be an electron-transporting layer (“ETL”) or a hole-blocking layer, while the upper auxiliary layer 25 may be a hole-transporting layer (“HTL”) or an electron-blocking layer.

The lower auxiliary layer 15 and the upper auxiliary layer 25 may include an organic material, an inorganic material, or a composite of organic/inorganic materials, for example, polyethylene dioxythiophene:polystyrene sulfonate (“PEDOT:PSS”), polypyrrole, and the like. In an alternative embodiment, either of the lower auxiliary layer 15 and the upper auxiliary layer 25 may be omitted.

The photoactive layer 30 may include an inorganic nanostructure body 30a and a light-absorbing body 30b. In the illustrated embodiment, the inorganic nanostructure body 30a may be an electron acceptor including an n-type inorganic semiconductor material, while the light-absorbing body 30b may be an electron donor including a p-type organic semiconductor material.

The inorganic nanostructure body 30a and the light-absorbing body 30b form a bulk heterojunction structure inside the photoactive layer 30. The bulk heterojunction structure generates a photocurrent when electron-hole pairs generated by light absorbed in the photoactive layer 30 are diffused into the interface of an electron acceptor and an electron donor, and are then separated into electrons and holes due to electron affinity of the two materials forming the interface of the electron acceptor and the electron donor. Then, the electrons move toward a cathode through the electron acceptor, while the holes move toward an anode through the electron donor.

The inorganic nanostructure body 30a is continually connected inside the photoactive layer 30, and forms an electron path all over the photo-active layer 30, through which electric charges may reach an electrode with little loss. The inorganic nanostructure body 30a is a single unitary indivisible member, as it is continually connected.

As shown in FIG. 1, the inorganic nanostructure body 30a may be continually connected and thus have, as an example, a tripod-like gyroid shape. In addition, the inorganic nanostructure body 30a may have a continually connected (e.g., single unitary indivisible) nanotube or nano-rod shape as shown in FIG. 2. However, it may not be limited thereto, and may have various shapes connected like a network.

The inorganic nanostructure body 30a may include inorganic nanostructures continually connected to each other and a plurality of pores (not shown). The pores may have, for example, a size (e.g., dimension) ranging from about 1 nanometer (nm) to about 100 nanometers (nm), but in particular, from about 1 nm to about 20 nm.

The inorganic nanostructure body 30a may have no particular limit if it is an n-type inorganic semiconductor, and includes, for example, a metal oxide, a semiconducting compound, or a combination thereof. In one embodiment, for example, the inorganic nanostructure body 30a may include zinc oxide, titanium oxide, tantalum oxide, tin oxide, zirconium oxide, lanthanum oxide, niobium oxide, copper oxide, strontium oxide, indium oxide, sodium titanate, cadmium sulfide, gallium arsenide, cadmium selenide, lead sulfide, gallium phosphide, cadmium telluride, or a combination thereof.

The light-absorbing body 30b is filled among the inorganic nanostructures of the inorganic nanostructure body 30a, and connected overall inside the photoactive layer 30. The light-absorbing body 30b is a single unitary indivisible member, as it is connected overall. The inorganic nanostructure body 30a is a first portion of the photoactive layer 30, while a remaining (second) portion of the photoactive layer 30 is the light-absorbing body 30b.

The light-absorbing body 30b may include a soluble low molecular compound, so that it may be prepared into a solution. Particles of the soluble low molecular compound may have a size that is smaller than a gap among the inorganic nanostructures of the inorganic nanostructure body 30a and/or a plurality of pores in the inorganic nanostructure 30a body. In one embodiment, for example, when the inorganic nanostructure body 30a includes a plurality of pores having a size ranging from about 1 nm to about 100 nm as aforementioned, the particles or material of the soluble low molecular compound may have a size smaller than about 1 nm to about 100 nm, and thus may be filled in the plurality of pores. The soluble low molecular compound of the light-absorbing body 30b may completely fill areas of the plurality of pores. When the inorganic nanostructure body 30a has a pore size ranging from about 1 nm to about 20 nm, the particles or material of the soluble low molecular compound is smaller than about 1 nm to about 20 nm and thus may be filled (e.g., completely) among the plurality of pores.

In this way, the soluble low molecular compound of the light-absorbing body 30b may fill a gap among the inorganic nanostructures and the plurality of pores in the inorganic nanostructures body 30a, and may thereby be continually connected in the photoactive layer 30. Accordingly, a hole path may be formed all over the photoactive layer 30 so that electric charges may move toward an electrode with little loss. The holes and the electrons are recombined at the interface of an electron acceptor and an electron donor, saving a current without loss.

When a polymer is used as the light-absorbing body 30b, the polymer has a larger particle size and a longer chain than a gap among the inorganic nanostructures and the plurality of pores of the inorganic nanostructure body 30a, and thus may not fill them. As a result, the light-absorbing body 30b may be hardly connected in the photoactive layer 30 (e.g., may not form a single unitary indivisible or continuous member). In addition, when a non-soluble low molecular compound is used as the light-absorbing body 30b, the non-soluble low molecular compound may not be uniformly connected due to the low solubility and high agglomerating property thereof.

The soluble low molecular compound of the light-absorbing body 30b may have no particular limit as long as it is dissolvable in a solvent. The soluble low molecular compound of the light-absorbing body 30b may include, for example, an organic material having a mass from about 3000 Daltons or less. When the soluble low molecular compound has a mass of about 3000 Daltons or less, the soluble low molecular compound may fill a gap among the inorganic nanostructures and a plurality of pores in the inorganic nanostructure body 30a without an additional process.

Furthermore, the soluble low molecular compound of the light-absorbing body 30b may have, for example, band gap energy ranging from about 1 electron volt (eV) to about 2.5 electron volts (eV), and lowest unoccupied molecular orbital (“LUMO”) energy ranging from about −3.0 eV to about −4.0 eV. When the soluble low molecular compound of the light-absorbing body 30b has band gap energy and LUMO energy within the ranges detailed above, the soluble low molecular compound may work as an electron donor.

This soluble low molecular compound may include, for example, sub-naphthalocyanine (SubNc), sub-phthalocyanine (SubPc), 3,6-bis(5-(benzofuran-2-yl)thiophen-2-yl)-2,5-bis(2-ethylhexyl)pyrrolo[3,4-c]pyrrole-1,4-dione, DPP(TBFu)2, and the like.

The soluble low molecular compound may be dissolved in a solvent and thus used as a solution.

The solvent in which the soluble low molecular compound is dissolved may have no particular limit if the solvent can dissolve the soluble low molecular compound. The solvent may include, for example, at least one selected from the group consisting of deionized water, methanol, ethanol, propanol, isopropanol, 2-methoxyethanol, 2-ethoxyethanol, 2-propoxyethanol 2-butoxyethanol, methyl cellosolve, ethyl cellosolve, diethylene glycol methylether, diethylene glycol ethylether, dipropylene glycol methylether, toluene, xylene, hexane, heptane, octane, ethyl acetate, butyl acetate, diethylene glycol dimethylether, diethylene glycol dimethylethylether, methylmethoxy propionate, ethylethoxy propionate, ethyl lactate, propylene glycol methylether acetate, propylene glycol methylether, propylene glycol propylether, methylcellosolve acetate, ethylcellosolve acetate, diethylene glycol methylacetate, diethylene glycol ethylacetate, acetone, chloroform, methylisobutylketone, cyclohexanone, dimethyl formamide (DMF), N,N-dimethyl acetamide (DMAc), N-methyl-2-pyrrolidone, γ-butyrolactone, diethylether, ethylene glycol dimethylether, diglyme, tetrahydrofuran, chlorobenzene, dichlorobenzene, acetylacetone, and acetonitrile.

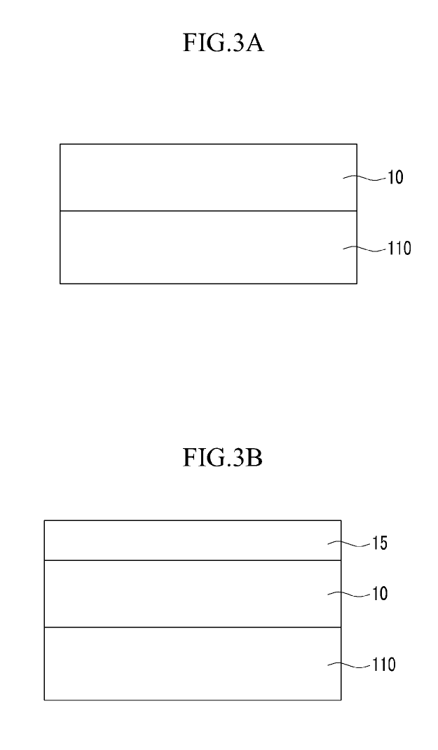

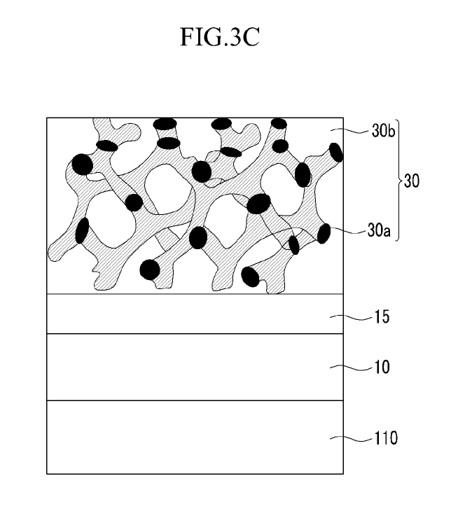

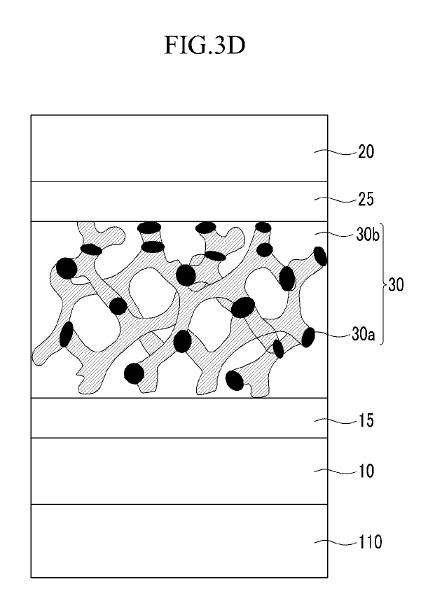

Hereinafter, an embodiment of a method of manufacturing an organic solar cell will be illustrated referring to FIGS. 3A to 3D.

FIGS. 3A to 3D provide cross-sectional views sequentially showing a method of manufacturing the organic solar cell of FIG. 1.

First, referring to FIG. 3A, a lower electrode is formed directly on an upper surface of a substrate 110. The lower electrode 10 may be formed, for example, in a sputtering method.

Next, referring to FIG. 3B, a lower auxiliary layer 15 is formed directly on an upper surface the lower electrode 10.

Then, referring to FIG. 3C, a photoactive layer 30 including inorganic nanostructures of the inorganic nanostructure body 30a continually connected to one another and a light-absorbing body 30b including a soluble low molecular compound, is formed directly on an upper surface of the lower auxiliary layer 15. In one embodiment, the photoactive layer 30 may be formed separate and prior to forming the photoactive layer 30 on the lower auxiliary layer 15. The photoactive layer 30 is formed by preparing the inorganic nanostructure body 30a and filling the soluble low molecular compound of the light-absorbing body 30b as a solution among the inorganic nanostructures of the inorganic nanostructure body 30a.

In an embodiment, after first forming the inorganic nanostructure body 30a, a solution including the soluble low molecular compound may be coated in a spin coating method and the like to fill a gap among the inorganic nanostructures and/or pores in the inorganic nanostructure body 30a. Alternatively, a photoactive layer 30 may be disposed using a solution including both inorganic nanostructures body 30a and a soluble low molecular compound.

Referring to FIG. 3D, an upper auxiliary layer 25 and an upper electrode 20 are sequentially formed directly on an upper surface of the light-absorbing layer 30, to finally form the organic solar cell of FIG. 1.

Hereinafter, the embodiments are illustrated in more detail with reference to examples of fabricating an organic solar cell. However, the following examples are embodiments and are not limiting of the invention.

### EXAMPLE 1

ITO is laminated on a glass substrate. The resulting product is ultrasonic wave cleansed with distilled water, acetone, and isopropyl alcohol in order for 10 minutes, respectively, and then dried. Next, a gyroid-shaped inorganic nanostructure including titanium oxide TiO₂ is formed on the ITO layer. The gyroid-shaped inorganic nanostructure may include titanium oxide (TiO₂) and a porous block copolymer template. The porous block copolymer may include poly(4-fluorostyrene)-b-poly(D,L-lactide) (PFS-b-PLA). Specifically, titanium oxide (TiO₂) is disposed to be 50 nm thick on an ITO layer in a spray pyrolysis deposition method.

Then, poly(4-fluorostyrene)-b-poly(D,L-lactide) (PFS-b-PLA), which is a block copolymer, is disposed. Then, the block copolymer is annealed at 180 degrees Celsius (° C.) for 35 hours, and cooled to room temperature. The block copolymer is dipped in water-soluble base and selectively removed to form a porous block copolymer mold. Next, the porous block copolymer mold is removed, after forming a nanostructure including titanium oxide inside the porous block copolymer mold by performing electrochemical replication. Then, 10 milligrams (mg) of DPP(TBFu)2 (molecular weight or mass: 756 Daltons) is dissolved in 1 milliliter (ml) of chlorobenzene. The solution is filled among the nanostructures.

### EXAMPLE 2

ITO is laminated on a glass substrate. The resulting product is ultrasonic wave cleansed with distilled water, acetone, and isopropyl alcohol in order, respectively, for 10 minutes, and then dried. Next, a bicontinuous network structure including titanium oxide TiO₂ is formed on the ITO layer. The bicontinuous network structure may be formed using titanium tetraisopropoxide (“TTIP”), which is a precursor of titanium oxide (TiO₂), and poly(stryrene-block-poly(ethylene oxide)) (PS-b-PEO) as a block copolymer. Specifically, titanium oxide (TiO₂) (no pores) is disposed to be 20 nm thick on the ITO layer.

Then, a solution prepared by mixing poly(stryrene)-b-poly(ethylene oxide) as a block copolymer and TTIP in a weight ratio of 1:1 is spin-coated thereon. The prepared substrate is annealed at 400° C. for 5 hours, and cooled to room temperature. In this way, a bicontinuous network structure including titanium oxide is formed. Then, the nanostructure is filled with a solution prepared by dissolving 10 mg of sub-naphthalocyanine (SubNc, molecular weight or mass: 579 Daltons) in 1 ml of dichlorobenzene.

### COMPARATIVE EXAMPLE 1

An organic solar cell is fabricated according to the same method as Example 1, except for using [6,6]-phenyl-C61-butyric acid methyl ester (“PCBM”), a fullerene derivative, instead of the nanostructure.

### COMPARATIVE EXAMPLE 2

An organic solar cell is fabricated according to the same method as Example 1, except for using poly[2-methoxy-5-(2′-ethylhexyloxy)-1,4-phenylenevinylene] (“MEH-PPV”) instead of a solution including a low molecular compound prepared by dissolving DPP(TBFu)2 in chlorobenzene.

### Evaluation

The organic solar cells according to Examples 1 and 2, and Comparative Examples 1 and 2 are evaluated regarding internal quantum efficiency (“IQE”), external quantum efficiency (“EQE”), and photo-efficiency. The results are provided in Table 1.

TABLE 1

| | IQE (%) | EQE (%) | Efficiency (%) |
|---|---|---|---|
| Example 1 | ≈100 | >70 | >6% |
| Example 2 | ≈100 | — | — |
| Comparative Example 1 | — | <50 | 4.4% |
| Comparative Example 2 | — | — | 0.71% |

As shown in Table 1, the organic solar cells according to Examples 1 and 2 have internal quantum efficiency near 100%. The organic solar cell of Example 1 has excellent external quantum efficiency compared with the organic solar cell of Comparative Example 1. In addition, the organic solar cell of Example 1 has excellent efficiency compared with the organic solar cell of Comparative Examples 1 and 2.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. An organic solar cell comprising:
a first electrode;
a second electrode facing the first electrode; and
a photoactive layer disposed between the first and second electrodes,
wherein the photoactive layer comprises:
inorganic nanostructures continually connected to one another, and
a light-absorbing body among the inorganic nanostructures, and comprising a soluble low molecular compound.

2. The organic solar cell of claim 1, wherein the light-absorbing body is continually connected in the photoactive layer.

3. The organic solar cell of claim 1, wherein
the inorganic nanostructures are an electron acceptor, and
the light-absorbing body is an electron donor.

4. The organic solar cell of claim 1, wherein
the inorganic nanostructures are an n-type semiconductor, and
the light-absorbing body is a p-type semiconductor.

5. The organic solar cell of claim 1, wherein the inorganic nanostructures comprise one selected from a metal oxide, a semiconducting compound, and a combination thereof.

6. The organic solar cell of claim 5, wherein the inorganic nanostructures comprise one selected from zinc oxide, titanium oxide, tantalum oxide, tin oxide, zirconium oxide, lanthanum oxide, niobium oxide, copper oxide, strontium oxide, indium oxide, sodium titanate, cadmium sulfide, gallium arsenide, cadmium selenide, lead sulfide, gallium phosphide, cadmium telluride, and a combination thereof.

7. The organic solar cell of claim 1, wherein the soluble low molecular compound of the light-absorbing body comprises an organic material with mass of about 3000 Daltons or less.

8. The organic solar cell of claim 7, wherein the soluble low molecular compound has band gap energy ranging from 1 electron volt to about 2.5 electron volts, and lowest unoccupied molecular orbit energy ranging from about −3.0 electron volts to about −4.0 electron volts.

9. The organic solar cell of claim 1, wherein the soluble low molecular compound of the light-absorbing body has a dimension smaller than a gap among the inorganic nanostructures.

10. The organic solar cell of claim 1, wherein the inorganic nanostructures include a plurality of pores having a dimension larger than a dimension of the soluble low molecular compound.

11. The organic solar cell of claim 1, wherein the inorganic nanostructures include a plurality of pores having a dimension ranging from about 1 nanometer to about 100 nanometers, and the light-absorbing body is filled in the plurality of pores.

12. The organic solar cell of claim 1, wherein the inorganic nanostructures include a plurality of pores having a dimension ranging from about 1 nanometer to about 20 nanometers, and the light-absorbing body is filled in the plurality of pores.

13. The organic solar cell of claim 1, wherein the inorganic nanostructures have at least one shape selected from nanotubes, nano-rods, a gyroid, a network, and a combination thereof.

14. A method of the organic solar cell, the method comprising:
forming a first electrode;
disposing a photoactive layer on the first electrode, the photoactive layer comprising:
inorganic nanostructures continually connected to one another; and
a light-absorbing body comprising a soluble low molecular compound; and
forming a second electrode on the photoactive layer.

15. The method of claim 14, wherein the disposing a photoactive layer comprises:
preparing the inorganic nanostructures, and
filling the soluble low molecular compound of the light-absorbing body as a solution among the inorganic nanostructures.

16. The method of claim 14, wherein
the inorganic nanostructures are an n-type electron-acceptor, and
the light-absorbing body is a p-type electron-donor.

17. The method of claim 16, wherein the inorganic nanostructures comprise one selected from a metal oxide, a semiconducting compound, and a combination thereof.

18. The method of claim 17, wherein the inorganic nanostructures comprise one selected from zinc oxide, titanium oxide, tantalum oxide, tin oxide, zirconium oxide, lanthanum oxide, niobium oxide, copper oxide, strontium oxide, indium oxide, sodium titanate, cadmium sulfide, gallium arsenide, cadmium selenide, lead sulfide, gallium phosphide, cadmium telluride, and a combination thereof.

19. The method of claim 17, wherein the soluble low molecular compound of the light-absorbing body has a mass of 3000 Daltons or less.

20. The method of claim 19, wherein the soluble low molecular compound has band gap energy ranging from about 1 electron volt to about 2.5 electron volts, and lowest unoccupied molecular orbit energy ranging from about −3.0 electron volts to about −4.0 electron volts.
